(19) United States
(12) Patent Application Publication
(10) Pub. No.: US 2024/0328445 A1
(43) Pub. Date: Oct. 3, 2024

(54) ANTI-WEAR SCREW

(71) Applicant: Auras Technology Co., Ltd., New Taipei City (TW)

(72) Inventors: Cheng-Ju CHANG, New Taipei City (TW); Moo-Ting CHOU, New Taipei City (TW); Yi-Le CHENG, New Taipei City (TW); Wan-Hsuan LIN, New Taipei City (TW); Chung-Chien SU, New Taipei City (TW)

(21) Appl. No.: 18/523,176

(22) Filed: Nov. 29, 2023

Related U.S. Application Data
(60) Provisional application No. 63/455,480, filed on Mar. 29, 2023.

(51) Int. Cl. F16B 5/02; F16B 5/06

(52) U.S. Cl. CPC F16B 5/0266; F16B 5/0621; H05K 7/2039

(57) ABSTRACT

An anti-wear screw includes a U-shaped anti-wear clip and a locking screw. The U-shaped anti-wear clip is used to clamp on a heat dissipation substrate, and the locking screw is passed through the U-shaped anti-wear clip to fix the heat dissipation substrate. In addition, the anti-wear screw further includes a pressure spring installed between the locking screw and the U-shaped anti-wear clip to exert pressure on the U-shaped anti-wear clip and the heat dissipation substrate.

### RELATED APPLICATIONS

This application claims priority to U.S. Provisional Application Ser. No. 63/455,480, filed Mar. 29, 2023, the disclosures of which are incorporated herein by reference in their entireties.

### TECHNICAL FIELD

The present disclosure relates to an anti-wear screw. More particularly, the present disclosure relates to an anti-wear screw able to install conveniently.

### BACKGROUND

With the advancement of technology, electronic products have become more popular, and gradually changed the life or work of many people. As the calculating power of the computers increases, the temperature control of the electronic components such as the central processing units is more important when the electronic components are working.

Electronic components such as the central processing units generate heat during operation and require proper cooling to achieve the best performance. In order to keep the central processing unit and other electronic components operating at a proper temperature, a liquid cooling device or an air cooling device is usually used.

In addition, due to the increasing number of cores of the central processing unit, the memory capacity is also increasing and faster. When the heat generated by the central processing unit is increasing, the volume and performance of the required cooling device must also increase. Therefore, the heat dissipation area of the heat dissipation fins required by the computer device is also gradually increased.

Therefore, there is a need to firmly fix the heat dissipation device on a surface of the central processing unit to effectively reduce the operating temperature of the central processing unit so as to improve the working efficiency of the overall computer device.

### SUMMARY

The summary of the present invention is intended to provide a simplified description of the disclosure to enable readers to have a basic understanding of the disclosure. The summary of the present invention is not a complete overview of the disclosure, and it is not intended to point out the importance of the embodiments/key elements of the present invention or define the scope of the invention.

One objective of the embodiments of the present invention is to provide an anti-wear screw able to prevent wear of the heat dissipation substrate and stabilize a contact force between the heat dissipation device and the central processing unit so as to further improve the heat dissipation efficiency of the overall computer device.

To achieve these and other advantages and in accordance with the objective of the embodiments of the present invention, as the embodiment broadly describes herein, the embodiments of the present invention provides an anti-wear screw including a U-shaped anti-wear clip and a locking screw. The U-shaped anti-wear clip is used to clamp on a heat dissipation substrate, and the locking screw passes through the U-shaped anti-wear clip to fix the heat dissipation substrate.

In some embodiments, the anti-wear screw further includes a pressure spring installed between the locking screw and the U-shaped anti-wear clip to exert pressure on the U-shaped anti-wear clip and the heat dissipation substrate.

In some embodiments, the U-shaped anti-wear clip includes an upper clamping arm, a connecting portion and a lower clamping arm. The connecting portion is connected to the upper clamping arm and the lower clamping arm is connected to the connecting portion. In addition, the upper clamping arm and the lower clamping arm have a length difference, and a length of the lower clamping arm is greater than a length of the upper clamping arm.

In some embodiments, the U-shaped anti-wear clip includes a first guiding portion and a second guiding portion, the first guiding portion is formed at a terminal portion of the upper clamping arm and is bent upwardly, and the second guiding portion is formed at a terminal portion of the lower clamping arm and is bent downwardly.

In some embodiments, the upper clamping arm and the lower clamping arm respectively include a V-shaped guiding notch.

In some embodiments, the V-shaped guiding notch of the lower clamping arm includes a smallest width, and the smallest width is smaller than an outer diameter of the locking screw.

In some embodiments, the locking screw includes a first portion, a second portion, a third portion and a screw head. The first portion has a first outer diameter, the second portion has a second outer diameter, and the second portion is connected to the first portion. The third portion has a third outer diameter connected to the second portion, and the second outer diameter is smaller than the first outer diameter and the third outer diameter. In addition, the screw head has a fourth outer diameter, the screw head is connected to the third portion, and the fourth outer diameter is greater than the first outer diameter, the second outer diameter and the third outer diameter.

In some embodiments, the first outer diameter is greater than or equal to the third outer diameter.

In some embodiments, the lower clamping arm of the U-shaped anti-wear clip includes a first opening communicated with a V-shaped guiding notch of the lower clamping arm, wherein the upper clamping arm of the U-shaped anti-wear clip includes a second opening communicated with a V-shaped guiding notch of the upper clamping arm, and a second opening inner diameter of the second opening is greater than a first opening inner diameter of the first opening.

In some embodiments, the first opening further includes a first opening entrance width, the first opening entrance width is smaller than the first opening inner diameter, and the second outer diameter of the second portion of the locking screw is between the first opening entrance width and the first opening inner diameter.

In some embodiments, the third outer diameter of the third portion of the locking screw is smaller than the second opening inner diameter of the second opening, the third outer diameter of the third portion of the locking screw is greater than the first opening inner diameter of the first opening, a spring outer diameter of the pressure spring is greater than the second opening inner diameter of the second opening.

In some embodiments, the heat dissipation substrate includes a first notch, a first notch width of the first notch is greater than the first opening inner diameter of the first opening and the second opening inner diameter of the second opening.

In some embodiments, the first opening inner diameter is smaller than the first outer diameter of the first portion of the locking screw.

In some embodiments, the heat dissipation substrate further includes a third notch under the heat dissipation substrate, and the lower clamping arm and the second guiding portion are located in the third notch.

In some embodiments, the locking screw includes an internal thread.

In some embodiments, the U-shaped anti-wear clip includes a fixing protrusion, and the heat dissipation substrate includes a fixing indentation to couple to the fixing protrusion so as to stably lock the U-shaped anti-wear clip on the heat dissipation substrate.

In some embodiments, the heat dissipation substrate includes a second notch to store the connecting portion of the U-shaped anti-wear clip.

In some embodiments, the locking screw and the U-shaped anti-wear clip are made of plastic material.

Hence, the anti-wear screw may effectively fix the heat dissipation device to the circuit board and stably contact the heat dissipation substrate to the heat source on the circuit board, and facilitate a user to install the anti-wear screw on the heat dissipation substrate of the heat dissipation device so as to effectively improve the assembly efficiency of the heat dissipation device and the heat dissipation efficiency of the computer equipment.

### BRIEF DESCRIPTION OF THE DRAWINGS

The disclosure can be more fully understood by reading the following detailed description of the embodiment, with reference made to the accompanying drawings as follows:

FIG. 1 illustrates a schematic exploded perspective diagram of an anti-wear screw according to one embodiment of the present invention;

FIG. 2 is a schematic perspective diagram of the anti-wear screw installed on a heat dissipation substrate;

FIG. 3 is a schematic partial diagram of the heat dissipation substrate;

FIG. 4 is a schematic side view of a U-shaped anti-wear clip of the anti-wear screw;

FIG. 5 is a schematic top view of the U-shaped anti-wear clip of the anti-wear screw;

FIG. 6 is a schematic partial cross-sectional diagram of the anti-wear screw and the heat dissipation substrate; and

FIG. 7 is a schematic perspective diagram of a heat dissipation device equipped with the anti-wear screw.

### DETAILED DESCRIPTION OF THE PREFERRED EMBODIMENT

The following is a detailed description of the embodiments in conjunction with the accompanying drawings, but the provided embodiments are not intended to limit the scope of the disclosure, and the description of the structure and operation is not used to limit the execution sequence thereof. The structure of the recombination of components and the resulting devices with equal functions are all within the scope of this disclosure. In addition, the drawings are for illustration purposes only, and are not drawn according to the original scale. For ease of understanding, the same reference numbers are used in the drawings and the description to refer to the same or like parts.

In addition, the terms used in the entire description and the scope of the patent application, unless otherwise specified, usually have the usual meaning of each term used in this field, in the content disclosed here and in the special content. Some terms used to describe the disclosure are discussed below or elsewhere in this specification to provide additional guidance to those skilled in the art in the disclosure.

In the implementation mode and the scope of the present application, unless the article is specifically limited in the context, “a” and “the” can generally refer to a single or pluralities. In the steps, the numbering is only used to conveniently describe the steps, rather than to limit the sequence and implementation.

Secondly, the words “comprising”, “including”, “having”, “containing” and the like used in the present application are all open language, meaning including but not limited to.

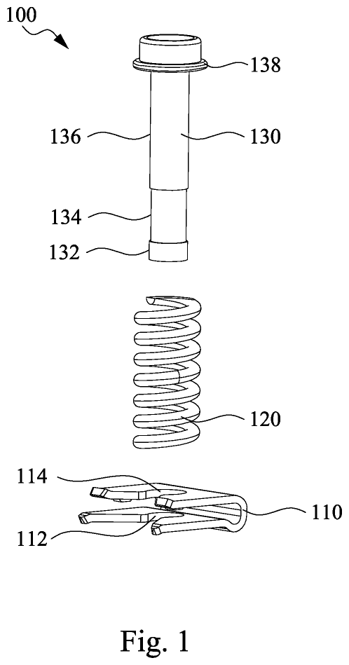

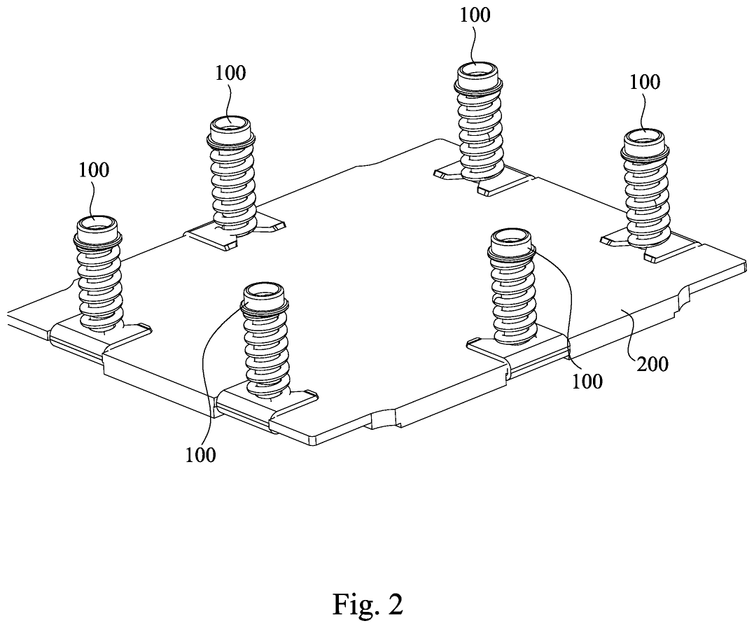

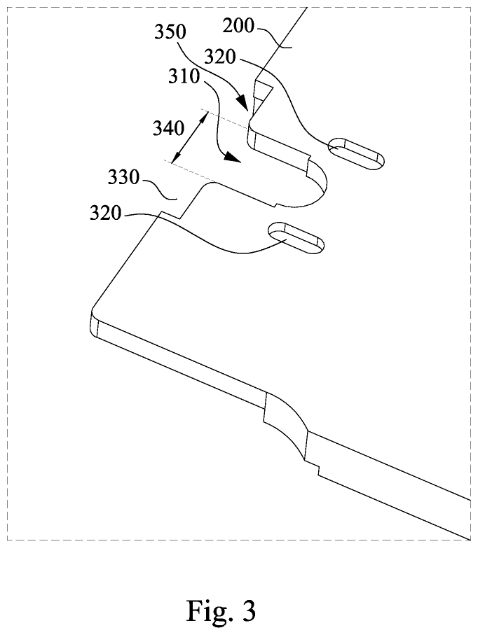

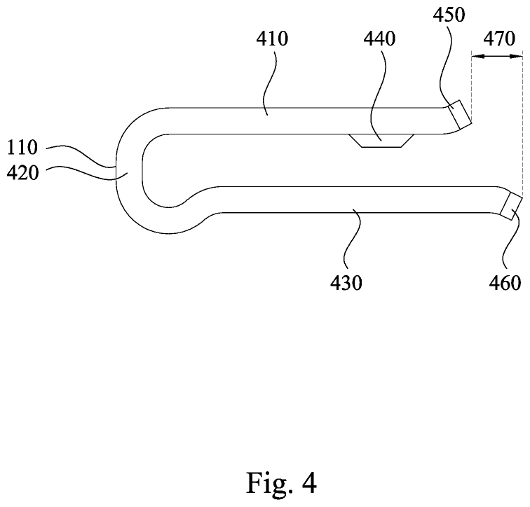

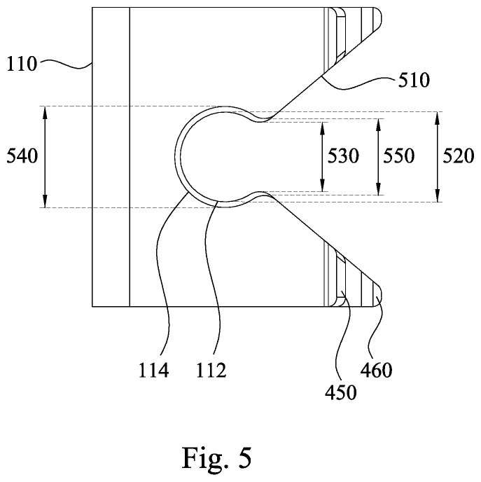

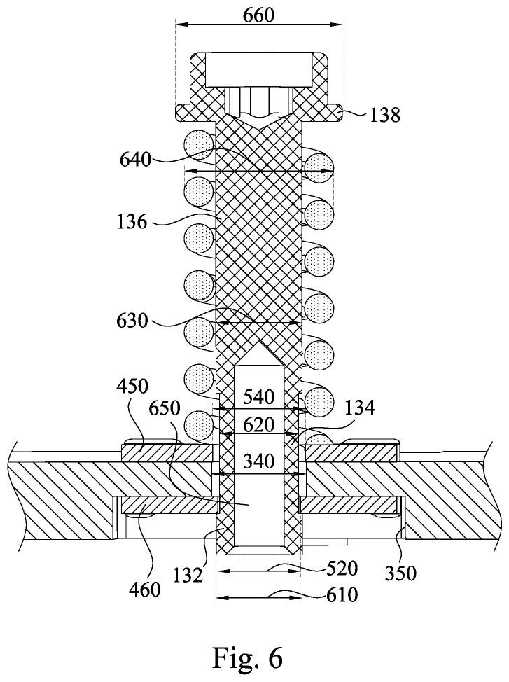

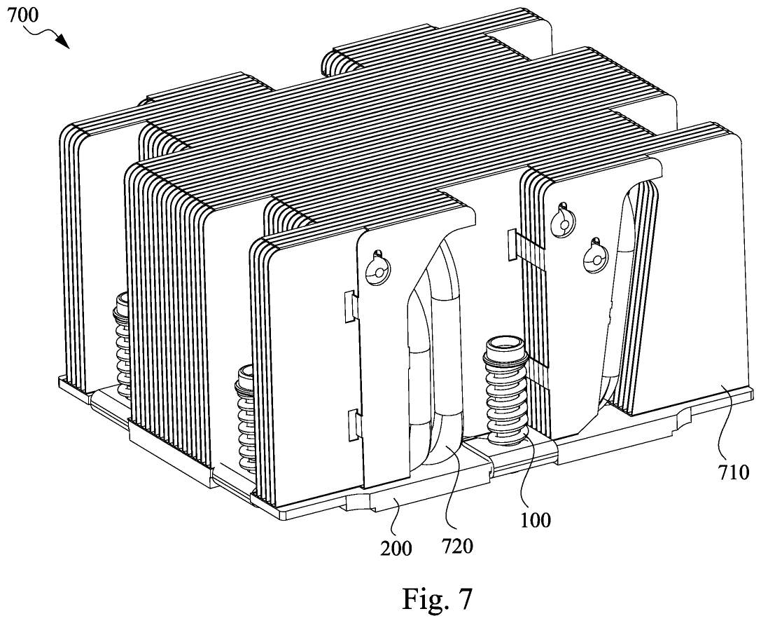

FIG. 1 illustrates a schematic exploded perspective diagram of an anti-wear screw according to one embodiment of the present invention, FIG. 2 illustrates a schematic perspective diagram of the anti-wear screw installed on a heat dissipation substrate, FIG. 3 illustrates a schematic partial diagram of the heat dissipation substrate, FIG. 4 illustrates a schematic side view of a U-shaped anti-wear clip of the anti-wear screw, FIG. 5 illustrates a schematic top view of the U-shaped anti-wear clip of the anti-wear screw, FIG. 6 illustrates a schematic partial cross-sectional diagram of the anti-wear screw and the heat dissipation substrate and FIG. 7 illustrates a schematic perspective diagram of a heat dissipation device equipped with the anti-wear screw.

First referring to FIG. 7, as shown in the drawing, the heat dissipation device 700 includes a plurality of heat dissipation fins 710, a plurality of heat pipes 720, a plurality of anti-wear screws 100 and a heat dissipation substrate 200. The heat pipes 720 pass through the heat dissipation fins 710, and the heat dissipation fins 710 and the heat pipes 720 are fixed on the heat dissipation substrate 200 to conveniently fix the heat dissipation device 700 on a circuit board with the anti-wear screws 100. For example, the heat dissipation device 700 is fixed on a main board of a computer device with the anti-wear screws 100 to provide a stable pressure on the heat dissipation device 700 to contact the central processing unit on the main board so that the heat dissipation device 700 may contact the central processing unit to reduce the working temperature of the central processing unit. In addition, the anti-wear screws 100 may equipped on a heat dissipation device of a graphics processing unit or any other heat dissipation device, without departing from the spirit and protection scope of the present invention.

Referring to FIG. 1, as shown in the drawing, the anti-wear screw 100 includes a U-shaped anti-wear clip 110, a pressure spring 120 and a locking screw 130. The U-shaped anti-wear clip 110 is used to clamp on the heat dissipation substrate 200, and the locking screw 130 is passed through the U-shaped anti-wear clip 110 to fix the heat dissipation substrate 200 on a circuit board so that the heat dissipation substrate 200 may contact a heat source, e.g. a central processing unit or a graphics processing unit, on the circuit board.

The pressure spring 120 is installed between the locking screw 130 and the U-shaped anti-wear clip 110 and surrounds the locking screw 130 to exert pressure on the U-shaped anti-wear clip 110 and the heat dissipation substrate 200 to provide a stable pressure on the U-shaped anti-wear clip 110 and the heat dissipation substrate 200 so that the heat dissipation substrate 200 may stably contact the heat source of the circuit board.

In some embodiments, simultaneously referring to FIG. 2, as show in the drawings, each anti-wear screw 100 may provide a pressure force about 20 to 32 Kilograms. Therefore, six anti-wear screws 100 may provide a pressure force about 130 to 190 Kilograms to allow the heat dissipation substrate 200 stably contacting the heat source on the circuit board.

Simultaneously referring from FIG. 3 to FIG. 5, as show in the drawings, the U-shaped anti-wear clip 110 includes an upper clamping arm 410, a connecting portion 420 and a lower clamping arm 430. The connecting portion 420 is connected between the upper clamping arm 410 and the lower clamping arm 430, and the lengths of the upper clamping arm 410 and the lower clamping arm 430 are different. For example, the length of the lower clamping arm 430 is greater than the length of the upper clamping arm 410 to form a length difference 470 between the upper clamping arm 410 and the lower clamping arm 430 so as to conveniently install the U-shaped anti-wear clip 110 on the heat dissipation substrate 200 by a user.

In some embodiments, a first guiding portion 450 is formed at a terminal portion of the upper clamping arm 410, and a second guiding portion 460 is formed at a terminal portion of the lower clamping arm 430 so as to conveniently install the U-shaped anti-wear clip 110 on the heat dissipation substrate 200. The first guiding portion 450 is bent upwardly at the terminal portion of the upper clamping arm 410, and the second guiding portion 460 is bent downwardly at the terminal portion of the lower clamping arm 430 to form an opening that is wider on the outside and narrower on the inside

In some embodiments, the upper clamping arm 410 and the lower clamping arm 430 of the U-shaped anti-wear clip 110 respectively include a V-shaped guiding notch 510 to conveniently install the locking screw 130 into the U-shaped anti-wear clip 110.

In addition, the V-shaped guiding notch 510 formed on the lower clamping arm 430 has a smallest width, referring to the first opening entrance width 530. The smallest width is preferably smaller than the outer diameter of the locking screw 130.

In some embodiments, the V-shaped guiding notch 510 formed on the upper clamping arm 410 has a smallest width, referring to the second opening entrance width 550. In addition, the second opening entrance width 550 may equal to the first opening entrance width 530, or the second opening entrance width 550 may be greater than the first opening entrance width 530, without departing from the spirit and protection scope of the present invention.

It is worth noting that the locking screw 130 at least includes a first portion 132 and a second portion 134, and the first portion 132 has a first outer diameter 610, and the second portion 134 has a second outer diameter 620. The second portion 134 is connected to the first portion 132, and the first outer diameter 610 is greater than the second outer diameter 620. The smallest width, e.g. the first opening entrance width 530, of the V-shaped guiding notch 510 of the lower clamping arm 430 is smaller than the second outer diameter 620 of the second portion 134 of the locking screw 130.

In some embodiments, the locking screw 130 further includes a screw head 138 and a third portion 136, the screw head 138 connected to the third portion 136 has a fourth outer diameter 660, and the third portion 136 connected to the second portion 134 has a third outer diameter 630. In addition, the fourth outer diameter 660 is greater than the first outer diameter 610, the second outer diameter 620 and the third outer diameter 630, and the first outer diameter 610 is also greater than or equal to the third outer diameter 630.

In some embodiments, the third outer diameter 630 is greater than or equal to the second outer diameter 620, and the third outer diameter 630 is preferably greater than the second outer diameter 620.

In addition, the lower clamping arm 430 of the U-shaped anti-wear clip 110 includes a first opening 112, the first opening 112 is communicated with the V-shaped guiding notch 510 of the lower clamping arm 430, and the upper clamping arm 410 of the U-shaped anti-wear clip 110 includes a second opening 114, the second opening 114 is communicated with the V-shaped guiding notch 510 of the upper clamping arm 410, and a second opening inner diameter 540 of the second opening 114 is greater than a first opening inner diameter 520 of the first opening 112.

In some embodiments, the first opening 112 further includes an first opening entrance width 530, and the first opening entrance width 530 is smaller than the first opening inner diameter 520.

In some embodiments, the first opening inner diameter 520 is smaller than a first outer diameter 610 of the locking screw 130.

In some embodiments, the second outer diameter 620 of the second portion 134 of the locking screw 130 is between the first opening entrance width 530 and the first opening inner diameter 520.

In some embodiments, a third outer diameter 630 of the third portion 136 of the locking screw 130 is smaller than the second opening inner diameter 540 of the second opening 114. In addition, in some embodiments, the third outer diameter 630 of the third portion 136 of the locking screw 130 and the second outer diameter 620 of the second portion 134 are smaller than the second opening inner diameter 540 of the second opening 114.

In some embodiments, the spring outer diameter 640 of the pressure spring 120 is greater than the second opening inner diameter 540 of the second opening 114. Therefore, both of the second portion 134 and the third portion 136 of the locking screw 130 may pass through the second opening 114 and move up and down to adjust the pressure exerted by the pressure spring 120 on the upper clamping arm 410 of the U-shaped anti-wear clip 110.

In some embodiments, the third outer diameter 630 of the third portion 136 of the locking screw 130 is greater than the first opening inner diameter 520 of the first opening 112 to effectively limit the travel of the locking screw 130.

In some embodiments, the heat dissipation substrate 200 includes a first notch 310, and the first notch width 340 of the first notch 310 is greater than the first opening inner diameter 520 of the first opening 112 and the second opening inner diameter 540 of the second opening 114 to avoid the locking screw 130 contacting to the heat dissipation substrate 200. Therefore, the anti-wear screw 100 of the present invention may use the U-shaped anti-wear clip 110 to cover two sides of the heat dissipation substrate 200 to protect the heat dissipation substrate 200 and avoid wear of the heat dissipation substrate 200 during tightening. In addition, the anti-wear screw 100 may prevent the locking screw 130 from directly contacting the heat dissipation substrate 200 during tightening so as to reduce deformation and wear of the heat dissipation substrate 200.

In some embodiments, the locking screw 130 includes an internal thread 650 to fix on a corresponding screw on the circuit board.

In some embodiments, the U-shaped anti-wear clip 110 further includes at least one fixing protrusion 440, and preferably includes a pair of fixing protrusions 440 symmetrically located on both sides of the second opening 114, and located on a bottom surface of the upper clamping arm 410 faced to the lower clamping arm 430, and the heat dissipation substrate 200 further includes a fixing indentation 320, and preferably includes a pair of fixing indentations 320 symmetrically located on both sides of the first notch 310. When the U-shaped anti-wear clip 110 installed on the heat dissipation substrate 200, the fixing protrusion 440 is coupled to the fixing indentation 320 to allow the U-shaped anti-wear clip 110 firmly locking on the heat dissipation substrate 200.

In some embodiments, simultaneously referring to FIG. 2 and FIG. 3, the heat dissipation substrate 200 further includes a second notch 330, the second notch 330 is located on one side of the heat dissipation substrate 200 and communicated with the first notch 310, the second notch 330 may accommodate the connecting portion 420 of the U-shaped anti-wear clip 110 to prevent the connecting portion 420 of the U-shaped anti-wear clip 110 from protruding outside the end surface of the heat dissipation substrate 200.

In some embodiments, simultaneously referring to FIG. 2, FIG. 3 and FIG. 6, the heat dissipation substrate 200 further includes a third notch 350 located under the heat dissipation substrate 200, and the lower clamping arm 430 and the second guiding portion 460 may be accommodated in the third notch 350 to prevent from protruding outside the bottom surface of the heat dissipation substrate 200 so as to install the heat dissipation substrate 200 conveniently.

Hence, when the anti-wear screw 100 is utilized, the locking screw 130 may first pass through the pressure spring 120, and the V-shaped guiding notch 510 of the U-shaped anti-wear clip 110 may align with the second portion 134 of the locking screw 130 to allow the locking screw 130 coupling into the first opening 112 and the second opening 114 by passing through the location indicated by the first opening entrance width 530. In addition, the first portion 132 of the locking screw 130 is located below the lower clamping arm 430 of the U-shaped anti-wear clip 110, and the second portion 134 of the locking screw 130 is located within the first opening 112 and the second opening 114. Furthermore, the pressure spring 120 is located above the upper clamping arm 410 to form a set of the anti-wear screw 100.

When the anti-wear screw 100 is fixed on the heat dissipation substrate 200, a user may conveniently place the lower clamping arm 430 of the U-shaped anti-wear clip 110 on the bottom surface of the heat dissipation substrate 200, and push the anti-wear screw 100 toward the inner side of the first notch 310 of the heat dissipation substrate 200 to allow the fixing protrusion 440 of the U-shaped anti-wear clip 110 stably engaging with the fixing indentation 320 of the heat dissipation substrate 200 so as to conveniently and firmly lock the U-shaped anti-wear clip 110 on the heat dissipation substrate 200. Therefore, the anti-wear screw 100 may be firmly fixed on the heat dissipation substrate 200.

In some embodiments, the locking screw 130 and the U-shaped anti-wear clip 110 of the anti-wear screw 100 are made of plastic material, and the pressure spring 120 may made of metal material. Therefore, the metal shavings due to wear of the metal material of a conventional anti-wear screw made of metal can be effectively avoided. In addition, the heat dissipation substrate 200 is made of a high thermal conductivity metal, such as copper or aluminum.

Accordingly, the anti-wear screw disclosed by the present invention may effectively fix the heat dissipation device to the circuit board and stably contact the heat dissipation substrate to the heat source on the circuit board, and facilitate a user to install the anti-wear screw on the heat dissipation substrate of the heat dissipation device so as to effectively improve the assembly efficiency of the heat dissipation device and the heat dissipation efficiency of the computer equipment.

Although the present disclosure has been disclosed above in terms of implementation, it is not intended to limit the present disclosure. Any person with ordinary knowledge in the field may make various variations and modifications without departing from the spirit and scope of the disclosure. Therefore, the spirit and scope of the appended claims should not be limited to the description of the embodiments contained herein.

What is claimed is:

1. An anti-wear screw, comprising:
a U-shaped anti-wear clip clamping on a heat dissipation substrate; and
a locking screw passing through the U-shaped anti-wear clip to fix the heat dissipation substrate.

2. The anti-wear screw of claim 1, further comprising:
a pressure spring installed between the locking screw and the U-shaped anti-wear clip to exert pressure on the U-shaped anti-wear clip and the heat dissipation substrate.

3. The anti-wear screw of claim 2, wherein the U-shaped anti-wear clip comprises:
an upper clamping arm;
a connecting portion connecting to the upper clamping arm; and
a lower clamping arm connecting to the connecting portion, wherein the upper clamping arm and the lower clamping arm have a length difference, and a length of the lower clamping arm is greater than a length of the upper clamping arm.

4. The anti-wear screw of claim 3, wherein the U-shaped anti-wear clip comprises a first guiding portion and a second guiding portion, the first guiding portion is formed at a terminal portion of the upper clamping arm and is bent upwardly, and the second guiding portion is formed at a terminal portion of the lower clamping arm and is bent downwardly.

5. The anti-wear screw of claim 3, wherein the upper clamping arm and the lower clamping arm respectively comprise a V-shaped guiding notch.

6. The anti-wear screw of claim 5, wherein the V-shaped guiding notch of the lower clamping arm comprises a smallest width, and the smallest width is smaller than an outer diameter of the locking screw.

7. The anti-wear screw of claim 6, wherein the locking screw comprises:
a first portion having a first outer diameter;
a second portion having a second outer diameter, wherein the second portion is connected to the first portion;
a third portion having a third outer diameter connected to the second portion, wherein the second outer diameter is smaller than the first outer diameter and the third outer diameter; and
a screw head having a fourth outer diameter, wherein the screw head is connected to the third portion and the fourth outer diameter is greater than the first outer diameter, the second outer diameter and the third outer diameter.

8. The anti-wear screw of claim 7, wherein the first outer diameter is greater than or equal to the third outer diameter.

9. The anti-wear screw of claim 8, wherein the lower clamping arm of the U-shaped anti-wear clip comprises a first opening communicated with a V-shaped guiding notch of the lower clamping arm, wherein the upper clamping arm of the U-shaped anti-wear clip comprises a second opening communicated with a V-shaped guiding notch of the upper clamping arm, and a second opening inner diameter of the second opening is greater than a first opening inner diameter of the first opening.

10. The anti-wear screw of claim 9, wherein the first opening further comprises a first opening entrance width, the first opening entrance width is smaller than the first opening inner diameter, and the second outer diameter of the second portion of the locking screw is between the first opening entrance width and the first opening inner diameter.

11. The anti-wear screw of claim 9, wherein the third outer diameter of the third portion of the locking screw is smaller than the second opening inner diameter of the second opening, the third outer diameter of the third portion of the locking screw is greater than the first opening inner diameter of the first opening, a spring outer diameter of the pressure spring is greater than the second opening inner diameter of the second opening.

12. The anti-wear screw of claim 9, wherein the heat dissipation substrate comprises a first notch, a first notch width of the first notch is greater than the first opening inner diameter of the first opening and the second opening inner diameter of the second opening.

13. The anti-wear screw of claim 9, wherein the first opening inner diameter is smaller than the first outer diameter of the first portion of the locking screw.

14. The anti-wear screw of claim 4, wherein the heat dissipation substrate further comprises a third notch under the heat dissipation substrate, and the lower clamping arm and the second guiding portion are located in the third notch.

15. The anti-wear screw of claim 1, wherein the locking screw comprises an internal thread.

16. The anti-wear screw of claim 1, wherein the U-shaped anti-wear clip comprises a fixing protrusion, and the heat dissipation substrate comprises a fixing indentation to couple to the fixing protrusion so as to stably lock the U-shaped anti-wear clip on the heat dissipation substrate.

17. The anti-wear screw of claim 3, wherein the heat dissipation substrate comprises a second notch to store the connecting portion of the U-shaped anti-wear clip.

18. The anti-wear screw of claim 1, wherein the locking screw and the U-shaped anti-wear clip are made of plastic material.
